(19) United States
(12) Patent Application Publication
(10) Pub. No.: US 2014/0305496 A1
(43) Pub. Date: Oct. 16, 2014

(54) SOLAR CELL MODULE

(71) Applicant: LG INNOTEK CO., LTD., Seoul (KR)

(72) Inventor: Seung Hoon Nam, Seoul (KR)

(73) Assignee: LG INNOTEK CO., LTD., Seoul (KR)

(21) Appl. No.: 14/354,459

(22) PCT Filed: Oct. 25, 2012
(86) PCT No.: PCT/KR2012/008800

§ 371 Date: Apr. 25, 2014

(30) Foreign Application Priority Data
Oct. 25, 2011 (KR) 10-2011-0109151

(51) Int. Cl. H01L 31/048

(52) U.S. Cl. CPC H01L 31/048
USPC 136/251

(57) ABSTRACT

A solar cell module includes a plurality of solar cells having a back electrode layer, a light absorbing layer, and a front electrode layer which are sequentially disposed on a support substrate, an upper panel on the solar cells, sealing layers disposed between an outer peripheral region of the support substrate and the upper panel for sealing the support substrate and the upper panel, and a moisture absorption layer between the sealing layers.

### TECHNICAL FIELD

The embodiment relates to a solar cell module having a moisture absorption layer and a sealing layer.

### BACKGROUND ART

Solar cells may be defined as devices to convert light energy into electrical energy by using a photovoltaic effect of generating electrons when light is incident onto a P-N junction diode. The solar cell may be classified into a silicon solar cell, a compound semiconductor solar cell mainly including a group I-III-VI compound or a group III-V compound, a dye-sensitized solar cell, and an organic solar cell according to materials constituting the junction diode.

The minimum unit of the solar cell is a cell. In general, one cell generates a very small voltage of about 0.5V to about 0.6V. Therefore, a panel-shape structure of connecting a plurality of cells to each other in series on a substrate to generate voltages in a range of several voltages to several hundreds of voltages is referred to as a module, and a structure having several modules installed in a frame is referred to as a solar cell apparatus.

The solar cell apparatus must have resistance against external moisture (H₂O) or external oxygen (O₂), and the problem related to the reliability must be solved in order to improve the performance of the solar cell. According to the related art, in order to solve the above problem, a sealing treatment is performed with respect to the solar cell. However, even though the solar cell is sealed, moisture is infiltrated into the solar cell apparatus along the interfacial surface between a substrate and a sealing, so that a solar cell electrode is corroded, thereby degrading the performance of the solar cell.

### DISCLOSURE OF INVENTION

### Technical Problem

The embodiment provides a solar cell module capable of improving the reliability and stability and a method of providing the same.

### Solution to Problem

According to the first embodiment, there is provided a solar cell module including: a plurality of solar cells having a back electrode layer, a light absorbing layer, and a front electrode layer which are sequentially disposed on a support substrate; an upper panel on the solar cells; sealing layers disposed between an outer peripheral region of the support substrate and the upper panel for sealing the support substrate and the upper panel; and a moisture absorption layer between the sealing layers.

According to the second embodiment, there is provided a solar cell module including: a plurality of solar cells having a back electrode layer, a light absorbing layer, and a front electrode layer which are sequentially disposed on a support substrate; an upper panel on the solar cells; a buffer layer between an outer peripheral region of the support substrate and the upper panel; sealing layers disposed on the buffer layer for sealing the support substrate and the upper panel; and a moisture absorption layer between the sealing layers.

### Advantageous Effects of Invention

According to the solar cell module of the embodiment, the moisture absorption layers may be formed between the plurality of sealing layers in an outer peripheral region of the support substrate, thereby minimizing the infiltration of moisture (H₂O) or oxygen (O₂) into the solar cell along an interfacial surface. That is, the solar cell module according to the embodiment efficiently protects solar cells from moisture (H₂O) or oxygen (O₂) so the stability and reliability of the device can be significantly improved.

According to the solar cell module of the embodiment, the buffer layer is formed between the support substrate and the sealing layer, so that cure degrees of the sealing layers can be increased upon sealing the support substrate and the upper panel.

### BRIEF DESCRIPTION OF DRAWINGS

FIG. 1 is an exploded view showing a solar cell module according to a first embodiment;

FIG. 2 is a sectional view showing a section of a solar cell module according to the first embodiment;

FIGS. 3 to 5 are sectional views showing a section of a solar cell module according to a second embodiment.

### BEST MODE FOR CARRYING OUT THE INVENTION

In the description of the embodiments, it will be understood that when a substrate, a layer, a film or an electrode is referred to as being on or under another substrate, another layer, another film or another electrode, it can be directly or indirectly on the other substrate, the other layer, the other film, or the other electrode, or one or more intervening layers may also be present. Such a position of the layer has been described with reference to the drawings. The size of the elements shown in the drawings may be exaggerated for the purpose of explanation and may not utterly reflect the actual size.

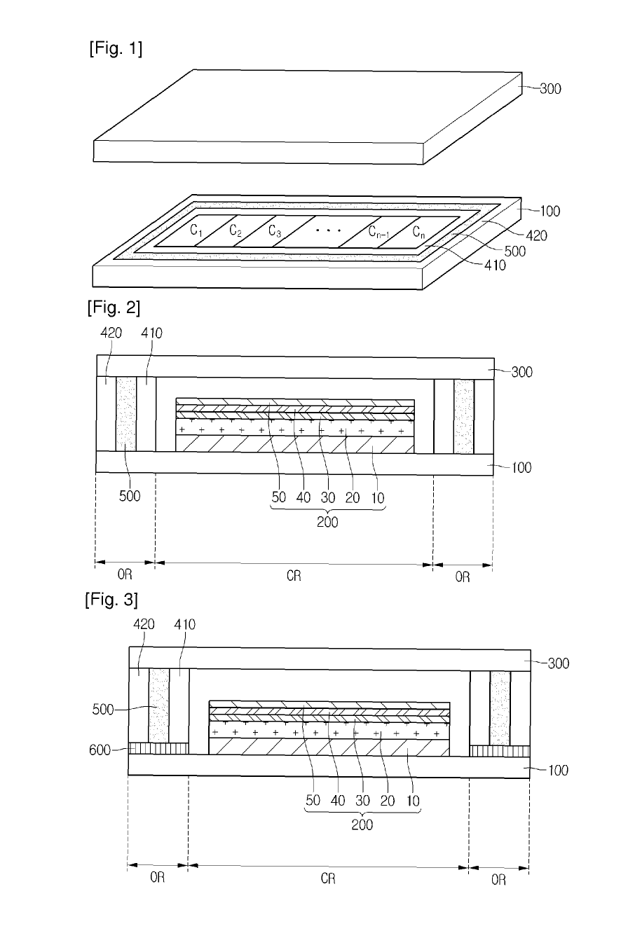

FIG. 1 is an exploded view showing a solar cell module according to a first embodiment. FIG. 2 is a sectional view showing a section of a solar cell module according to the first embodiment.

Referring to FIGS. 1 and 2, the solar cell module according to the embodiment includes a support substrate 100, solar cells 200, an upper panel 300, sealing layers 410 and 420, and a moisture absorption layer 500. In detail, the solar cell 200 includes a back electrode layer 10, a light absorbing layer 20, a buffer layer 30, a high resistance buffer layer 40, and a front electrode layer 50.

The support substrate 100 has a plate shape, and supports the solar cell 200, the upper panel 300, the sealing layers 410 and 420, and the moisture absorption layer 500. The support substrate 100 may be transparent, and may be rigid or flexible. The support substrate 100 may include an insulator.

For example, the support substrate 100 may include a glass substrate, a plastic substrate, or a metallic substrate. In more detail, the support substrate 100 may include a soda lime glass substrate.

In addition, the support substrate 100 may include a ceramic substrate including alumina, stainless steel, or polymer having a flexible property.

The support substrate 100 may be divided into a central region CR and an outer region OR. The central region CR refers to an active area (AA) on which the solar cells are formed. The outer region OR is a region surrounding the central region CR, and refers to a non-active area (NAA) on which the solar cells 200 are not formed.

The solar cells 200 are disposed in the central region CR of the support substrate 100. The solar cells 200 include a plurality of solar cells, which are electrically connected with each other. For example, the solar cells are serially connected to each other, but the embodiment is not limited thereto. Thus, the solar cells 200 may convert solar light into electric energy.

Referring to FIG. 2, the solar cells 200 includes the back electrode layer 10 disposed on the substrate 100, the light absorbing layer 20 disposed on the back electrode layer 10, and the front electrode layer 50 disposed on the light absorbing layer 20. The solar cells 200 may further include the buffer layer 30 and the high resistance buffer layer 40 formed between the light absorbing layer 20 and the front electrode layer 50.

The back electrode layer 10 may include one selected from the group consisting of molybdenum (Mo), gold (Au), aluminum (Al), chromium (Cr), tungsten (W), and copper (Cu). Among the above elements, the Mo may represent the thermal expansion coefficient similar to that of the support substrate 100, so the Mo has superior adhesive property with respect to the support substrate 100, thereby preventing the back electrode layer 10 from being delaminated from the support substrate 100.

The light absorbing layer 20 is formed on the back electrode layer 10. The light absorbing layer 20 may include group I-III-VI compounds. For instance, the light absorbing layer 20 may include the Cu(In,Ga)Se₂ (CIGS) crystal structure, the Cu(In)Se₂ crystal structure, or the Cu(Ga)Se₂ crystal structure.

The buffer layer 30 is provided on the light absorbing layer 20. The buffer layer 30 may include CdS, ZnS, In_{X}S_{Y} or In_{X}Se_{Y}Zn(O, OH). The high-resistance buffer layer 40 is disposed on the buffer layer 30. The high-resistance buffer layer 40 includes i-ZnO, which is not doped with impurities.

The front electrode layer 50 may be disposed on the light absorbing layer 20. For example, the front electrode layer 50 may make direct contact with the high resistance buffer layer 40 on the light absorbing layer 20.

The front electrode layer 50 may include a transparent conductive material. In addition, the front electrode layer 50 may have the characteristics of an N type semi-conductor. In this case, the front electrode layer 50 forms an N type semiconductor with the buffer layer 30 to make a PN junction with the light absorbing layer 20 serving as a P type semiconductor layer.

The upper panel 300 is disposed on the solar cells 200. The protective panel 300 can protect the solar cells 200 from the external impact and/or impurities. The upper panel 40 is transparent. For instance, the upper panel 300 includes tempered glass. The upper panel 300 is sealed together with the support substrate 100 by the sealing layers 410 and 420.

The sealing layers 410 and 420 are disposed between the support substrate 100 and the upper panel 300. In detail, the sealing layers 410 and 420 are disposed between the outer peripheral region OR of the support substrate 100 and the upper panel 300. That is, the sealing layers 410 and 420 may be coated on the outer peripheral region OR of a top surface of the support substrate 100. Accordingly, outer peripheral portions of the solar cells 200 are surrounded by the sealing layers 410 and 420. For example, the sealing layers 410 and 420 may be coated to surround four sides of the solar cells 200.

The sealing layers 410 and 420 may include a material for sealing the support substrate and the upper panel using ultraviolet ray, visible ray, or heat, which is not specially limited if the material is generally used in the art. For example, the sealing layers 410 and 420 may include epoxy resin or silicon resin, but the embodiment is not limited thereto.

Referring to FIG. 2, the sealing layers 410 and 420 include a first sealing layer 410 and a second sealing layer 420. Although only two sealing layers are shown and described in FIG. 2 and the embodiment, the embodiment is not limited thereto. The second sealing layer 420 may be disposed around the first sealing layer 410. For example, the second sealing layer 420 may be disposed in an inner peripheral region or an outer peripheral region of the first sealing layer 410.

In the solar cell module according to the embodiment, a plurality of sealing layers 410 and 420 may be formed to easily seal the support substrate and the upper panel. Accordingly, the sealing layers 410 and 420 can minimize the infiltration of moisture (H₂O) or oxygen (O₂) into the solar cell along an interfacial surface. That is, the sealing layers 410 and 420 efficiently protect solar cells 200 from moisture (H₂O) or oxygen (O₂) so the stability and reliability of the device can be significantly improved.

The moisture absorption layers 500 are disposed between the sealing layers 410 and 420, respectively. In the solar cell module according to the embodiment, a plurality of sealing layers 410 and 420 are formed and the moisture absorption layers 50 are formed between the sealing layers 410 and 420 so that the moisture absorption layers 500 can be fixed without a separate receiving groove. A material of the moisture absorption layer 500 is not specially limited if the material is cured by heat or light capable of absorbing moisture or oxygen.

Referring to FIG. 2, the moisture absorption layer 500 is formed between the first sealing layer 410 and the second sealing layer 420. In detail, the moisture absorption layer 500 may be partially or fully interposed between the first sealing layer 410 and the second sealing layer 420. For example, the moisture absorption layer 500 may be formed in only regions corresponding to four corners of the support substrate 100.

The moisture absorption 500 may be transparent or opaque. In detail, it is preferable that the moisture absorption layer 500 is transparent. For example, the transparent moisture absorption layer 500 may include CaO, BaO, LiO, or ZrO. More preferably, the transparent moisture absorption layer 500 may include CaO, but the embodiment is not limited. The opaque moisture absorption layer 500 may include one or plural materials selected from the group consisting of barium oxide, potassium oxide, aluminum oxide, lithium sulfate, sodium sulfate, calcium sulfate, magnesium sulfate, cobalt sulfate, gallium sulfate, titanium sulfate, calcium chloride, and calcium nitrate, but the embodiment is not limited thereto.

The moisture absorption layer 500 may include an adhesive material and a plurality of moisture absorption particles dispersed in the adhesive material. The adhesive material may easily fix the moisture absorption particles. The adhesive material may include thermoplastic resin.

In this case, an average diameter of the moisture absorption particles may be in the range of about 1 to about 10, but the embodiment is not limited thereto. When the average diameter of the moisture absorption particles are about 10 or less, it can prevent the moisture absorption layer from being cracked or delaminated according to temperature variation.

The moisture absorption layers 500 may be additionally disposed in an inner space between the support substrate 100 and the upper panel 300. The inner space is defined through the sealing of the support substrate 100 and the upper panel 300. The inner space may be a vacuum state or may be filled with inert gas such as neon or argon, or may be filled with liquids capable of performing the function the same as that of vacuum or inert gas. In detail, referring to FIG. 2, the moisture absorption 500 may be additionally disposed in an inner wall of the first sealing layer 410 in the inner space. The moisture absorption layer 500 may be additionally disposed on a bottom surface of the upper panel 300 in the inner space, but the embodiment is not limited thereto.

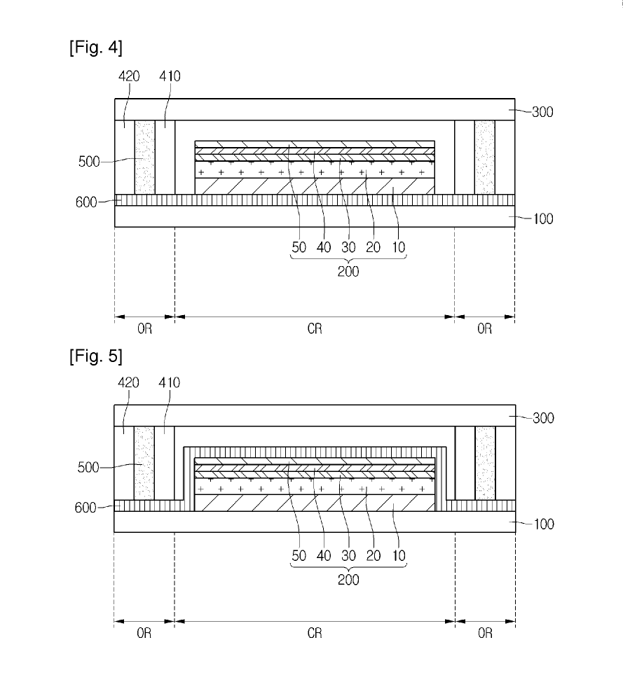

FIGS. 3 and 4 are sectional views showing a section of a solar cell module according to a second embodiment.

Referring to FIGS. 3 and 4, the support substrate 100 may include a soda lime glass substrate. In the soda lime glass substrate, Na+ ions are diffused into the light absorbing layer 300 during a manufacturing process, thereby improving photoelectric conversion efficiency of the solar cell, but may deteriorate adhesive strength and a degree of cure between the support substrate and the upper panel. Accordingly, in the solar cell module of the second embodiment, the buffer layer 600 is additionally disposed between the support substrate 100 and the upper panel 300. The buffer layer 600 may prevent Na+ from being erupted from the soda lime glass substrate. Thus, the adhesive strength between the upper panel 300 and the buffer layer 600 may be improved. The buffer layer 600 may include one selected from the group consisting of SiO₂, Si₃N₄, solgel silica, organically modified ceramics (ORMOCER), and benzo cyclobutene (BCB), but the second embodiment is not limited thereto.

Referring to FIG. 3, the buffer layer 600 may be disposed on the outer peripheral region OR of the support substrate 100. That is, the buffer layer 600 may be disposed at a region in which the sealing layers 410 and 420 will be formed. Referring to FIG. 4, the buffer layer 600 may be formed not only in the outer peripheral region OR of the support substrate 100 but also in the central region CR of the support substrate 100. FIG. 4 illustrates that the solar cells 200 are formed on the buffer layer 600, but the embodiment is not limited thereto. That is, as shown in FIG. 5, the buffer layer 600 may be formed at upper sides of the solar cells 200.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell module comprising:
a plurality of solar cells having a back electrode layer, a light absorbing layer, and a front electrode layer which are sequentially disposed on a support substrate;
an upper panel on the solar cells;
sealing layers disposed between an outer peripheral region of the support substrate and the upper panel for sealing the support substrate and the upper panel; and
a moisture absorption layer between the sealing layers.

2. The solar cell module of claim 1, wherein the sealing layers comprise a first sealing layer and a second sealing layer disposed around the first sealing layer, and the moisture absorption layer is disposed between the first sealing layer and the second sealing layer.

3. The solar cell module of claim 1, wherein the moisture absorption layer comprises CaO, BaO, LiO, or ZrO.

4. The solar cell module of claim 1, wherein the moisture absorption layer is cured by heat or light.

5. The solar cell module of claim 1, wherein the moisture absorption layer comprises a moisture absorption particle having a diameter in a range of 1 μm to 10 μm.

6. The solar cell module of claim 1, wherein an inner space between the support substrate and the upper panel is maintained in a vacuum state.

7. The solar cell module of claim 6, wherein the moisture absorption layer is further disposed in the inner space between the support substrate and the upper panel.

8. The solar cell module of claim 1, wherein the sealing layer comprises epoxy resin or silicon resin.

9. A solar cell module comprising:
a plurality of solar cells having a back electrode layer, a light absorbing layer, and a front electrode layer which are sequentially disposed on a support substrate;
an upper panel on the solar cells;
a buffer layer between an outer peripheral region of the support substrate and the upper panel;
sealing layers disposed on the buffer layer for sealing the support substrate and the upper panel; and
a moisture absorption layer between the sealing layers.

10. The solar cell module of claim 9, wherein the support substrate comprises a soda lime glass substrate.

11. The solar cell module of claim 9, wherein the buffer layer comprises SiO₂, Si₃N₄, or solgel silica.

12. The solar cell module of claim 9, wherein the buffer layer is further disposed on the solar cells.

13. The solar cell module of claim 9, wherein the moisture absorption layer comprises CaO, BaO, LiO, or ZrO.

14. The solar cell module of claim 9, wherein the moisture absorption layer is cured by heat or light.

15. The solar cell module of claim 9, wherein the moisture absorption layer comprises a moisture absorption particle having a diameter in a range of 1 μm to 10 μm.

16. The solar cell module of claim 9, wherein the buffer layer is further disposed at a region in which the sealing layer will be formed.

17. The solar cell module of claim 9, wherein an inner space between the support substrate and the upper panel is maintained in a vacuum state.

18. The solar cell module of claim 9, wherein an inner space between the support substrate and the upper panel is filled with inert gas or liquids capable of performing the function the same as that of vacuum or inert gas.

19. The solar cell module of claim 1, wherein an inner space between the support substrate and the upper panel is filled with inert gas or liquids capable of performing the function the same as that of vacuum or inert gas.
